(19) United States
(12) Patent Application Publication
(10) Pub. No.: US 2011/0286400 A1
(43) Pub. Date: Nov. 24, 2011

(54) METHOD FOR SENDING AND RECEIVING CLOCK, APPARATUS FOR TRANSMITTING CLOCK

(75) Inventor: Xiaoming Fu, Guangdong (CN)

(73) Assignee: ZTE CORPORATION, Shenzhen City, Guangdong (CN)

(21) Appl. No.: 13/146,770

(22) PCT Filed: Sep. 24, 2009
(86) PCT No.: PCT/CN09/74171

§ 371 Date: Jul. 28, 2011

(30) Foreign Application Priority Data
Feb. 4, 2009 (CN) 200910005147.9

(51) Int. Cl. H04W 56/00; H03L 7/00

(52) U.S. Cl. 370/328; 327/144; 327/153; 327/151

(57) ABSTRACT

A method for sending and receiving a clock and an apparatus for transmitting the clock. Several kinds of clocks are encoded and framed at a sending port so that the clocks needed by all modes of base stations are transmitted in one pair of interconnecting lines. A receiving port can precisely recover the needed clock out. This not only reduces the number of interconnecting lines on the backboard and improves flexibility, but also avoids that the clock decoded out by the receiving port might be imprecise.

### TECHNICAL FIELD

The present invention relates to the field of communication, and more especially, to a method for sending and receiving a clock among boards in a multimode base station, as well as an apparatus for transmitting the clock.

### BACKGROUND OF THE RELATED ART

A clock board in the base station is used to extract the clock from the reference clock and recover the clock, and to generate and distribute a new clock to the other boards according to the system requirements. The clock needing to be transmitted generally comprises two clock signals, where the first clock signal is used to transmit a certain clock frequency, and the second clock signal is used to transmit a timing signal. Under the conventional base station architecture, one base station only needs to bear the services of one mode, for example, the CDMA base station is only used in the CDMA system, therefore the requirements for the clock is also straightforward, and the clock board only needs to distribute a certain clock frequency and a certain timing signal according to the system requirements.

For the multimode base station, the services of multiple modes, such as CDMA/WCDMA/GSM and so on, are required to be compatible in the same base station architecture. Different modes, however, have different requirements for the first and second clock signals, thus the multimode base station needs to consider how to transmit a plurality of clocks.

In the prior art, when a multimode base station transmits a plurality of clocks, different hardware connections are used to transmit different clocks. For example, the CDMA system requires that the first clock and the second clock are through one pair of lines, while the WCDMA system requires that the first clock and the second clock are through another pair of lines, and so on, the user board selects the input clock according to its own requirements. This method not only adds the backboard traces, but also brings more work to the PCB design, which is not good for system extension.

### CONTENT OF THE INVENTION

The present invention provides a method for sending and receiving a clock and an apparatus for transmitting the clock to solve the technical problem in the prior art, and to transmit several kinds of clock signals on one pair of interconnecting lines.

In order to solve the above problem, the present invention provides a method for sending a clock, and the method comprises: a sending port selecting a first clock frequency, encoding second clocks of various modes, and sending the first clock frequency and the encoded second clocks to each receiving port via a pair of interconnecting lines.

Furthermore, the sending port calculates a common devisor of cycles of the second clocks before starting to encode the second clocks and determines a time delay T1 at an encoding stage, a time delay T2 at a sending stage and a time delay T3 at a decoding stage;

said sending port takes said common divisor as a cycle to encode the second clocks of various modes t1 before a cyclical timing signal arrives, where said t1=T1+T2+T3.

Furthermore, said sending port continuously sends said first clock frequency via a first clock transmission line; and

said sending port starts to send the encoded second clocks t2 before the cyclical timing signal arrives, where said t2=T2+T3.

Furthermore, said sending port arranging encoded codeword into a sequence after encoding the second clocks, and adding a guard bit, a start bit and an end bit to constitute a data frame with a fixed length, and then sending the data frame to the receiving port bit by bit via a second clock transmission line.

The present invention also provides a method for receiving a clock, comprising: each receiving port receiving a first clock frequency from a first clock transmission line, using said first clock frequency to count locally, and receiving an encoded second clock from a second clock transmission line and decoding the encoded second clock.

Furthermore, when the receiving port cannot decode the second clock correctly, the receiving port uses the first clock frequency to count to generate the second clock needed by said receiving port.

Furthermore, the encoded second clock is encapsulated into a data frame, and said data frame comprises a guard bit; after said receiving port receives the data frame, the receiving port judging whether the guard bit is correct or not, and if yes, decoding a codeword of a part corresponding to the receiving port, otherwise, discarding said data frame.

The present invention also provides an apparatus for sending a clock, comprising a sending port, a first clock transmission line and a second clock transmission line; wherein:

said sending port comprises a control module, one or more clock encoding modules and a sending module;

said control module is configured to select a first clock frequency and send the first clock frequency to the sending module;

each one of said a plurality of clock encoding modules corresponds to a second clock of one mode, and said clock encoding module is configured to encode a second clock of a corresponding mode and send an encoded codeword to the sending module;

said sending module is configured to send said first clock frequency via said first clock transmission line, as well as to send the encoded second clock via the second clock transmission line.

Furthermore, said control module is also configured to calculate a common divisor of cycles of all of the second clocks, and send the common divisor to each clock encoding module;

the control module is also configured to determine a time delay T1 at an encoding stage, a time delay T2 at a sending stage and a time delay t3 at a decoding stage; as well as sending a sign of starting to encode the second clock to each clock encoding module t1 before a cyclical timing signal arrives, where said t1=T1+T2+T3;

said clock encoding module is also configured to take said common divisor as a cycle to encode the corresponding second clock after receiving said sign of starting to encode the second clock.

Furthermore, said control module is also configured to send a sign of starting to send the second clock to the sending module t2 before the cyclical timing signal arrives, where said t2=T2+T3;

said sending module is also configured to, after receive the codeword sent from each clock encoding module, arrange said codeword into a sequence, and add a guard bit, a start bit and an end bit to constitute a data frame with a fixed length;

the sending module sends the first clock frequency continuously through the first clock transmission line after receiving the first clock frequency, and to send said data frame through the second clock transmission line after receiving said sign of starting to send the data frame.

The present invention also provides an apparatus for receiving a clock, comprising one or more receiving ports; wherein:

said receiving port comprises a decoding module and a clock phase-locked loop;

said clock phase-locked loop is configured to receiving a first clock frequency from a first clock transmission line;

said decoding module is configured to receive said data frame from a second clock transmission line and decoding a second clock out according to said data frame.

Furthermore, said clock phase-locked loop is also configured to recover a first clock needed by the receiving port at which the clock phase-locked loop is located according to the first clock frequency when the received first clock frequency is not a first clock needed by the receiving port.

Furthermore, the decoding module is also configured to judge whether a guard bit is correct or not after receiving said data frame, and decode corresponding codeword if yes, otherwise, discard said data frame and use said first clock to count locally to generate a second clock needed by the receiving port.

The present invention provides a method for sending and receiving a clock and an apparatus for transmitting the clock, several kinds of clocks are encoded and framed at the sending port according to the method of the present invention, so that several kinds of clock signals can be transmitted on one pair of interconnecting lines, the board at the receiving port precisely recovers the clock needed by itself according to the corresponding decoding rule.

### BRIEF DESCRIPTION OF DRAWINGS

FIG. 1 illustrates the structure of the apparatus for transmitting the clock in accordance with the present invention;

FIG. 2 is a sequential diagram of encoding in the method in accordance with an embodiment of the present invention;

FIG. 3 is a flow chart of the method for transmitting the clock in accordance with an embodiment of the present invention;

FIG. 4 is a sequential diagram of encoding and decoding in accordance with an embodiment of the present invention;

FIG. 5 illustrates the structure of the encoded data frame in accordance with an embodiment of the present invention.

### PREFERRED EMBODIMENTS OF THE PRESENT INVENTION

The present invention provides a method for sending and receiving a clock as well as an apparatus for transmitting the clock, several kinds of clocks are encoded and framed at the sending port according to the method of the present invention, so that these clocks can be transmitted on one pair of interconnecting lines. The board at the receiving port is able to precisely recover the clock needed by itself according to the corresponding decoding rule.

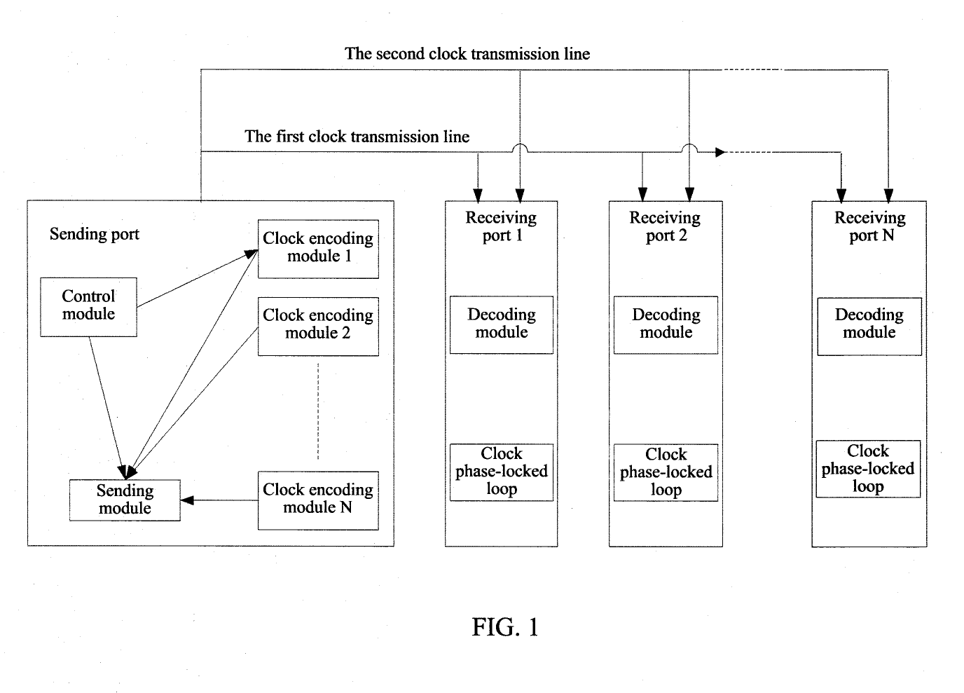

In the multimode base station, the clock board outputs a high stable reference frequency, which is called the first clock in the following, to the user board by locking and referring to the input clock; meanwhile, a reference clock with high precision should be provided to the user plane, and the reference clock is called the second clock. FIG. 1 illustrates the connection relationship between the clock plane in the multimode base station (the sending port in FIG. 1) and each user plane (the receiving port in FIG. 1), and the clock plane transmits the first and second clocks to each receiving port via the pair of interconnecting lines on the backboard. In order to adapt to the demands of a plurality of clocks in the multimode base station, it needs to encode the second clock. In the following, an example is used to illustrate the method for encoding and transmitting the clocks in the multimode base station.

This embodiment provides an apparatus for transmitting the clock, and as shown in FIG. 1, the apparatus comprises a sending port, a receiving port, a first clock transmission line and a second clock transmission line;

The sending port comprises a control module, one or more clock encoding modules, and a sending module; wherein:

the control module is used to select a suitable first clock frequency and send the first clock frequency to the sending module, where the first clock frequency is required to meet the requirement that the boards at the receiving ports should be able to recover clocks with different frequencies needed by themselves, in addition, it also needs to consider the sequential requirement of the components at the receiving ports, and the first clock frequency should not be too high;

the control module is also used to calculate the common divisor of all of the second clock cycle, and sends the common divisor to each clock encoding module; it is also used to determine the time delay T1 at the encoding stage, the time delay T2 at the sending stage and the time delay T3 at the decoding stage;

the control module is also used to send a sign of starting to encode the second clock to the clock encoding modules in different modes t1 before the cycle timing signal arrives, wherein t1=T1+T2+T3, and to send a sign of starting to send to the sending module t2 (t2=T2+T3) before the cyclical timing signal arrives;

the clock encoding module is used to, after receiving the sign of starting to encode the second clock, encode the second clock in this mode by taking the received common divisor as the cycle, where the encoding rule thereof is selected according to the requirement of the mode, and the present invention does not make any restriction to the encoding rules; the clock encoding module is also used to send the encoded codeword to the sending module;

the sending module is used to continuously send the first clock frequency through the first clock transmission line after receiving the first clock frequency, and also used to arrange the codeword sent from each clock encoding module into a sequence according to a predefined rule which can be but not limited to the rule shown in FIG. 5, in which the codes are sequentially arranged into a row, but the arranging order is not restricted; the sending module is also used to add a guard bit to the above sequence, and the guard bit can be but not limited to the parity code, it is also used to add a start bit and an end bit to the sequence to form a data frame, and it is also used to send the above data frame through the second clock transmission line after receiving the sign of starting to send.

The first clock signal is a clock signal with relatively high frequency, while the second clock signal is a timing signal with relatively low frequency; one second clock signal cycle comprises an integral number of the first clock signal cycles.

The receiving port comprises a decoding module and a clock phase-locked loop; wherein:

the clock phase-locked loop is used to receive the first clock frequency from the first clock transmission line, and directly use the first clock frequency if the first clock frequency is the clock frequency needed by itself, otherwise, the clock phase-locked array recovers its needed clock frequency according to the first clock frequency;

the decoding module is used to receive a data frame from the second clock transmission line, and decode the codeword corresponding to this mode according to the decoding rule corresponding to the encoding rule; it is also used to judge whether the guard bit is correct or not when the received data frame has a guard bit, and to decode the codeword of the corresponding part (the corresponding part is the encoding of the second clock of this mode) if yes, otherwise, to discard the data frame;

the decoding module is also used to make the recovered first clock count locally to generated the second clock needed by the receiving port when it cannot decode the second clock out correctly, otherwise, it synchronizes the decoded-out second clock with the second clock generated by counting locally.

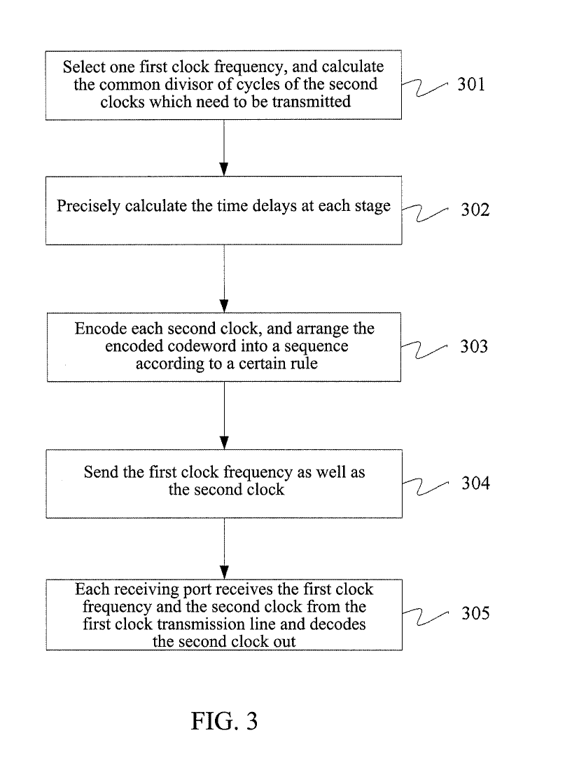

The present embodiment provides a method for transmitting a clock, as shown in FIG. 3, the method comprises the following steps:

step 301a: the sending port selects a suitable first clock frequency to be transmitted, and then proceed to step 304a;

since the boards of the receiving ports may be in different mode, their required clock frequencies may also be different, therefore, the selected first clock frequencies must meet the requirement that the boards of the receiving ports are able to recover frequency clocks required by themselves. In addition, it also needs to consider the sequential requirements of the components at the receiving port, and the first clock frequency should not be too high;

step 301b: the sending port calculates the common divisor of cycles for transmitting all of the second clocks to be transmitted, and then proceed to step 302;

For example, the CDMA system requests to take 2 seconds as one cycle to transmit the timing signal, the GSM system requests to take 60 ms as one cycle to transmit the timing signal, and the WCDMA system requests to take 10 ms as one cycle to transmit the timing signal, then 10 ms is the common divisor of cycles of all of the timing signals and can be selected as the cycle to send the encoded signal.

In this step, the first clock is used to count so as to generate a timing signal that takes the common divisor as one cycle.

Step 302: precisely calculate the time delay at each stage, including the time delay T1 at the encoding stage, the time delay T2 at the sending stage, and the time delay T3 at the decoding stage;

Step 303: the sending port takes the above common divisor as the cycle to encode individually according to each mode t1 before the cyclical timing signal arrives, and the codeword encoded by each encoding module is arranged into a sequence according to a certain rule, such as the rule shown in FIG. 5, in which the codeword is sequentially arranged into a row, although the arranging order is not restricted, and then a guard bit is added at the end of this sequence, and the guard bit can be but not limited to the parity code, and then a start bit and an end bit are added at the end of the sequence to form a data frame; wherein, t1=T1+T2+T3; the whole encoding process takes T1. Moreover, some data are reserved for extension (not shown in FIG. 5). Then proceed to step 304b.

Each encoding module might select the encoding rule according to the needs of the mode.

In this step, when the encoding clock cycle of the encoding module overlaps with the cyclical timing signal of the corresponding mode, output the valid encoding, otherwise, output the invalid encoding.

When the mode is determined, the length of the data frame formed is fixed.

Step 304a: the sending port sends the first clock frequency continuously through the first clock transmission line;

Step 304b: the sending port sends the data frame consisting of the encoded second clock through the second clock transmission line t2 (t2=T2+T3) before the cyclical timing signal arrives, and the data frame is send bit by bit to the interconnecting lines on the backboard;

Step 305a: each receiving port receives the first clock frequency from the first clock transmission line, and if the first clock frequency is the clock frequency needed by itself, the receiving port directly uses this first clock frequency, otherwise the receiving port recovers the clock frequency needed by itself via the clock phase-locked loop; afterwards, the receiving port uses the first clock to count locally to get a timing signal synchronized with the second clock, and the timing signal is generated cyclically;

Step 305b: each receiving port also receives the data frame consisting of the encoded second clock through the second clock transmission line, and decodes the codeword of the corresponding part in the data frame according to the decoding rule corresponding to the encoding rule to analyze the second clock needed by itself, and the codeword of the corresponding part is the part corresponding to the mode of the receiving port.

Furthermore, each receiving port judges whether the guard bit is correct or not after receiving the data frame, and decodes the codeword of the corresponding part if yes, otherwise, discards this data frame. If the receiving port decodes out the second clock correctly, the receiving port synchronizes the timing signal obtained by counting by the first clock with the decoded second clock, and if the receiving port cannot decode out the second clock since it does not receive the data frame for a certain period or determines that there is error bit in the codeword, it uses the timing signal to replace the second clock and distribute it to the other modules.

In the following, the present invention will be described in further detail with an application example.

The first clock frequency selected in the present example is 61.44 MHz which is a typical clock frequency transmitted using an optical module, meanwhile, the receiving port can lock the clock frequency needed by itself, such as 39.3216 MHz needed by the CDMA system and 13 MHz needed by the GSM system, with this clock frequency.

If a certain multimode base station is designed to compatible with CDMA, WCDMA, GSM, TD-SCDMA and WIMAX, different modes of base station systems have different requirements for the second clock. Wherein, CDMA requests to transmit a PP2S pulse whose cycle is 2s to align with the GPS in time; WCDMA requests to transmit a continuous frame synchronous signal generated with a cycle of 10 ms; GSM requests to transmit the continuous frame synchronous signals with a cycle of 60 ms; TD-SCDMA also requests to transmit the continuous frame synchronous signals with a cycle of 10 ms, WIMAX requests to transmit a PP1S pulse with a cycle of 1s, aligning with GPS in time. The implementation is as follows:

Step 1: calculate the maximum common divisor of all of the second clocks, and obviously to this base station, the maximum common divisor of the second clock is 10 ms.

Step 2: generate a pulse signal with a cycle of 10 ms, a pulse signal with a cycle of 2s, a pulse signal with a cycle of 60 ms, and a pulse signal with a cycle of 1s by counting using the first clock, and all these pulse signals align with the 10 ms pulse signal.

Step 3: precisely calculate the time delay T1 at the encoding stage, the time delay T2 at the sending stage and the time delay T3 at the decoding stage, when the first clock samples the 10 ms pulse signal, all modes of encoding modules start to encode the second clock individually.

For example, the CDMA encoding module generates a codeword A when a 10 ms pulse and a PP2S pulse are sampled at the same time, and generates another codeword B (which is an invalid encoding for the CDMA receiving port) when only the 10 ms pulse is sampled. While the GSM encoding module adds the frame number by 13 when both a 10 ms pulse and a 60 ms pulse are sampled, and keeps the frame number unchanged when only a 10 ms pulse is sampled, and other encoding modules also conform to their own rules for encoding when a 10 ms pulse comes. For example, for the TD-SCDMA encoding module, the CPU notifies the encoding module about the current time information when starting up the encoding module, the encoding module calculates out a value based on the current time information, and afterwards, adds 100 to this value per 10 ms. For the WCDMA module, the initial value is 0, and afterwards the initial value is added by one every 10 ms after the encoding module starts up.

The first clock is sent continuously, and the second clock is sent every 10 ms. For the GSM module, the data frame is invalid to the receiving port after 5 times of invalid decodings and can be discarded directly.

Step 4: arrange the codeword encoded by each encoding module into a sequence with a certain rule, and add some guard bits, such as the parity codes, to the sequence.

Step 5: send the codeword including the guard bits to the interconnecting lines on the backboard bit by bit, and the sending module is controlled by the first clock, moreover, the time point of sending each bit is the same.

Step 6: at each receiving port, use one decoding module to decode the received codeword according to the corresponding rule to get the second clock needed by the receiving port.

Step 7: the decoding module of each receiving port has the function of maintenance, that is, when the codeword is not received in a certain period or the received codeword has error inside, the decoding module might use the first clock to count locally, and continuously output the second clock needed by the receiving port. When the codeword sent from the clock board is correct, synchronize the second clock generated by counting locally with the decoded second clock.

Step 8: the clock in step 2 needs to be generated T before the reference to guarantee that the second clock recovered out by the receiving port aligns with the reference clock.

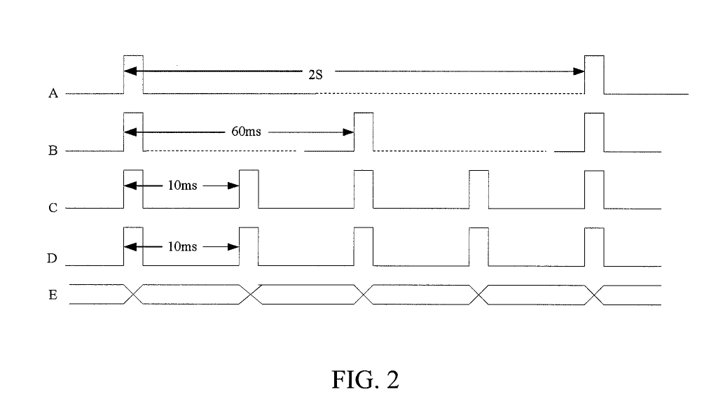

A in the accompanying FIG. 2 represents the PP2S pulse needed by CDMA, B represents the 60 ms pulse needed by GSM, C the 10 ms pulse needed by WCDMA, D the 10 ms pulse which is the maximum common divisor of the above three clocks, E the encoded second clock which changes per 10 ms.

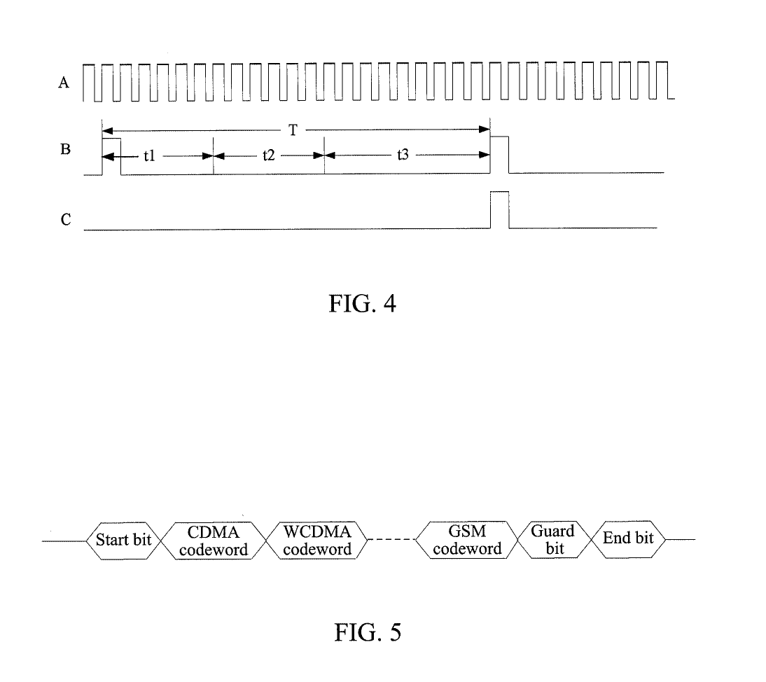

A in the accompanying FIG. 4 represents the first clock, the last pulse of B signal represents the signal of starting to encode the second clock, and the next pulse of B aligns with the reference signal. The meanings of T, T1, T2 and T3 are shown in the context. C represents the signal recovered from the receiving port, and the signal aligns with the reference signal.

With the technical scheme of the present invention, the clocks needed by all modes of base stations can be transmitted on one pair of interconnecting lines, and the receiving port can precisely recover the clock needed by itself, which not only reduces the number of interconnecting lines on the backboard and increases the flexibility, but also avoids that the clock recovered by the receiving port might not be correct.

### INDUSTRIAL APPLICABILITY

The method for sending and receiving a clock and the apparatus for transmitting the clock provided in the present invention encode and frame several kinds of clocks at the sending port, so that the clocks needed by all modes of base stations can be transmitted on one pair of interconnecting lines and the receiving port can precisely recover the clock needed by itself, which not only reduces the number of interconnecting lines on the backboard and increases the flexibility, but also avoids that the clock recovered by the receiving port might not be precise.

What is claimed is:

1. A method for sending a clock, and the method comprising:
a sending port selecting a first clock frequency, encoding second clocks of various modes, and sending the first clock frequency and the encoded second clocks to each receiving port via a pair of interconnecting lines.

2. The method of claim 1, before the step of said sending port encoding the second clocks of various modes, the method also comprising: the sending port calculating a common devisor of cycles of the second clocks of various modes and determining a time delay T1 at an encoding stage, a time delay T2 at a sending stage and a time delay T3 at a decoding stage;
wherein the step of said sending port encoding the second clocks of various modes comprises: said sending port taking said common divisor as a cycle to encode the second clocks of various modes t1 before a cyclical timing signal arrives, where said t1=T1+T2+T3.

3. The method of claim 2, wherein,
the step of said sending port sending said first clock frequency and the encoded second clocks to each receiving port comprises:
said sending port continuously sending said first clock frequency via a first clock transmission line; and
said sending port starting to send the encoded second clocks t2 before the cyclical timing signal arrives, where said t2=T2+T3.

4. The method of claim 1, wherein,
the step of said sending port sending the encoded second clocks to each receiving port comprises: said sending port arranging encoded codeword into a sequence after encoding the second clocks, and adding a guard bit, a start bit and an end bit to constitute a data frame with a fixed length, and then sending the data frame to the receiving port bit by bit via a second clock transmission line.

5. A method for receiving a clock, comprising:
each receiving port receiving a first clock frequency from a first clock transmission line, using said first clock frequency to count locally, and receiving an encoded second clock from a second clock transmission line and decoding the encoded second clock.

6. The method of claim 5, further comprising:
when the receiving port cannot decode the second clock correctly, the receiving port using the first clock frequency to count to generate the second clock needed by said receiving port.

7. The method of claim 5, wherein,
the encoded second clock is encapsulated into a data frame, and said data frame comprises a guard bit;
the step of said receiving port receiving said encoded second clock and decoding the encoded second clock comprises: after said receiving port receives the data frame, the receiving port judging whether the guard bit is correct or not, and if yes, decoding a codeword of a part corresponding to the receiving port, otherwise, discarding said data frame.

8. An apparatus for sending a clock, comprising a sending port, a first clock transmission line and a second clock transmission line; wherein
said sending port comprises a control module, one or more clock encoding modules and a sending module;
said control module is configured to select a first clock frequency and send the first clock frequency to the sending module;
each one of said a plurality of clock encoding modules corresponds to a second clock of one mode, and said clock encoding module is configured to encode a second clock of a corresponding mode and send an encoded codeword to the sending module;
said sending module is configured to send said first clock frequency via said first clock transmission line, as well as to send the encoded second clock via the second clock transmission line.

9. The apparatus of claim 8, wherein,
said control module is also configured to calculate a common divisor of cycles of all of the second clocks, and send the common divisor to each clock encoding module; to determine a time delay T1 at an encoding stage, a time delay T2 at a sending stage and a time delay t3 at a decoding stage; as well as sending a sign of starting to encode the second clock to each clock encoding module t1 before a cyclical timing signal arrives, where said t1=T1+T2+T3;
said clock encoding module is also configured to take said common divisor as a cycle to encode the corresponding second clock after receiving said sign of starting to encode the second clock.

10. The apparatus of claim 9, wherein,
said control module is also configured to send a sign of starting to send the second clock to the sending module t2 before the cyclical timing signal arrives, where said t2=T2+T3;
said sending module is also configured to, after receive the codeword sent from each clock encoding module, arrange said codeword into a sequence, and add a guard bit, a start bit and an end bit to constitute a data frame with a fixed length; and to send the first clock frequency through the first clock transmission line after receiving the first clock frequency, and to send said data frame through the second clock transmission line after receiving said sign of starting to send the data frame.

11. An apparatus for receiving a clock, comprising one or more receiving ports; wherein:
said receiving port comprises a decoding module and a clock phase-locked loop;
said clock phase-locked loop is configured to receiving a first clock frequency from a first clock transmission line;
said decoding module is configured to receive said data frame from a second clock transmission line and decoding a second clock out according to said data frame.

12. The apparatus of claim 11, wherein,
said clock phase-locked loop is also configured to recover a first clock needed by the receiving port at which the clock phase-locked loop is located according to the first clock frequency when the received first clock frequency is not a first clock needed by the receiving port.

13. The apparatus of claim 11, wherein,
said decoding module is also configured to judge whether a guard bit is correct or not after receiving said data frame, and decode a codeword corresponding to a mode of the receiving port at which the decoding module is located if yes, otherwise, discard said data frame and use said first clock frequency to count locally to generate a second clock needed by the receiving port at which the decoding module is located.
